(19) United States
(12) Patent Application Publication
(10) Pub. No.: US 2008/0142917 A1
(43) Pub. Date: Jun. 19, 2008

(54) Image sensor module, method of manufacturing the same, and camera module having the same

(75) Inventors: Kyoung Tai Lee, Yongin-si (KR); Seung Man Oh, Suwon-si (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRO-MECHANICS CO., LTD., Suwon (KR)

(21) Appl. No.: 12/000,336

(22) Filed: Dec. 11, 2007

(30) Foreign Application Priority Data
Dec. 14, 2006 (KR) 10-2006-0128169

(51) Int. Cl. H01L 31/0232; H01L 31/18

(52) U.S. Cl. 257/432; 257/434; 438/64; 257/E31.127

(57) ABSTRACT

Provided is an image sensor module including a lower substrate having a plurality of electrode pads formed on the outer portion of the top surface thereof; an upper substrate installed on the top surface of the lower substrate, the upper substrate having a window formed in the central portion thereof and a plurality of electrode pads formed on the bottom surface thereof to correspond to the respective electrode pads of the lower substrate, the window exposing the central portion of the top surface of the lower substrate; a conductive member interposed between the electrode pads of the lower substrate and the electrode pads of the upper substrate so as to form a conductive line for electrically connecting the electrode pads; and an image sensor module mounted on the top surface of the upper substrate.

### CROSS-REFERENCE TO RELATED APPLICATIONS

This application claims the benefit of Korean Patent Application No. 10-2006-0128169 filed with the Korea Intellectual Property Office on Dec. 14, 2006, the disclosure of which is incorporated herein by reference.

### BACKGROUND OF THE INVENTION

1. Field of the Invention

The present invention relates to an image sensor module, a method of manufacturing the same, and a camera module having the same.

2. Description of the Related Art

With the recent development of mobile terminals such as portable phones and personal digital assistants (PDAs), the mobile terminals provide a phone call function and are used as multi-convergence devices. The most representative of the multi-convergence is a camera module. The resolution of the camera module changes from 300,000 pixels (VGA) to 8,000,000 pixels. Moreover, the camera module provides various additional functions, such as auto-focusing (AF) and optical zoom. Generally, camera modules are applied to various IT devices, such as camera phones, smart phones, and mobile communication terminals.

The camera modules are manufactured by using main parts of charge coupled device (CCD) or complementary metal oxide semiconductor (CMOS) image sensors. Incident light transmitted through the lens is condensed by the image sensor and is stored as data in the memory. The stored data is displayed as an image through a display medium, such as liquid crystal display (LCD) or PC monitor.

Hereinafter, a conventional image sensor module and a conventional camera module will be described in detail with reference to accompanying drawings.

FIG. 1 is an exploded perspective view of a conventional COB camera module. FIG. 2 is an exploded perspective view of a conventional COF camera module. FIG. 3 is an exploded perspective view of a conventional socket-type camera module.

As shown in FIG. 1, the conventional COB camera module includes an RPCB (Rigid Printed Circuit Board) 11, an image sensor 12, an IR (Infrared) cut-off filter 13, a housing 14, and a lens barrel 15.

On the RPCB 11, various electronic parts, such as a capacitor, a resistor and so on, for driving the image sensor 12 and semiconductor elements are mounted. In particular, passive elements 17 for preventing noise of a camera module are mounted in one side of the image sensor 12 on the top surface of RPCB 11.

The image sensor 12 is composed of CCD or CMOS, and serves to convert light, incident through a lens group L via the IR cut-off filter 13, into an electrical signal.

The IR cut-off filter 13 is installed on a lower step portion of the housing 14 and serves to cut off long-wavelength infrared light included in light incident on the image sensor 12.

The lens barrel 15 has the lens group L mounted therein and is coupled to the housing 14 through a screw.

As shown in FIG. 2, the conventional COF camera module includes an FPCB (Flexible Printed Circuit Board) 21, an image sensor 22, an IR cut-off filter 23, a housing 24, and a lens barrel 25.

The FPCB 21 has a rectangular window 21a formed therein, and various electronic parts such as a capacitor, a resistor and so on for driving the image sensor 22 are mounted on the FPCB 21. In particular, passive elements 27 for preventing noise of the camera module are mounted in one side of the window 21a on the top surface of the FPCB 21.

The image sensor 22 is composed of CCD or CMOS and is mounted on the bottom surface of the FPCB 21. The image sensor 22 serves to convert light, incident through the window 21a of the FPCB 21, into an electrical signal.

The IR cut-off filter 23 is installed on the top surface of the FPCB 21 so as to cut off long-wavelength infrared light from light incident on the image sensor 22 through the window 21a of the FPCB 21.

The lens barrel 25 has a lens group L mounted therein and is assembled to the housing 24 through a screw.

The FPCB 21 has a connector (not shown) installed at an extended end thereof, the connector serving to electrically connect the camera module to an external device.

The conventional socket-type camera module is a module obtained by modifying the conventional COB camera module shown in FIG. 1. As shown in FIG. 3, a ceramic circuit 31 is used instead of the RPCB, in order to use side contact with a socket.

That is, the socket-type camera module includes a ceramic circuit 31, an image sensor 32, an IR cut-off filter 33, a housing 34, and a lens barrel 35. The ceramic circuit 31 has a pad 31a formed in a groove 31b formed in a side surface of the ceramic circuit 31, the pad 31a being formed for connection with a terminal of a socket. The groove 31b is formed in a lower portion of the side surface of the ceramic circuit 31 such that, when bond is coated so as to couple the ceramic circuit 31 and the housing 34, the coated bond does not drop into the pad 31a.

Further, the image sensor 32 is mounted in the center of the top surface of the ceramic circuit 31, and various electronic parts such as a capacitor, a resistor and so on for driving the image sensor 32 and semiconductor elements are mounted on the outer portion of the top surface. In particular, passive elements 37 for preventing noise of the camera module are mounted in one side of the image sensor 32 on the top surface of the ceramic circuit 31.

However, the conventional camera modules have the following problems.

The above-described camera modules need the passive elements 17, 27, and 37 for preventing noise, respectively. In this case, the passive element 17, 27, or 37 is mounted in one side of the image sensor 12, 22, or 32 on the top surface of the substrate 11, 21, or 31, so that the size of the camera module increases.

That is, since a space required for mounting the passive element 17, 27, or 37 on the top surface of the substrate 11, 21, or 31 in addition to the image sensor 12, 22, or 32 is necessary, the size of the substrate 11, 21, or 31 increases.

Further, as the size of the substrate 11, 21, or 31 is increased in a direction where the passive element 17, 27, or 37 is mounted, the center of the lens group L is not positioned in the center of the substrate 11, 21, or 31, and the shape of the camera module is deformed.

To solve this problem, when the size of the substrate 11, 21, or 31 is also increased in an opposite direction to the direction where the passive element 17, 27, or 37 is mounted, the size of the substrate is further increased.

The passive element 17, 27, or 37 may be mounted on the bottom surface of the substrate 11, 21, or 31. Such a structure is difficult to apply to the socket-type camera module. The height of the camera module inevitably increases, and a short circuit may occur when the camera module is connected to an external device.

Furthermore, in the conventional socket-type camera module, the expensive ceramic circuit 31 is inevitably used for the side-contact. Therefore, the manufacturing time and cost increases.

### SUMMARY OF THE INVENTION

An advantage of the present invention is that it provides an image sensor module, which can be reduced in size and of which the manufacturing time can be shortened so that a manufacturing cost can be reduced, a method of manufacturing the same, and a camera module having the same

Additional aspects and advantages of the present general inventive concept will be set forth in part in the description which follows and, in part, will be obvious from the description, or may be learned by practice of the general inventive concept.

According to an aspect of the invention, an image sensor module comprises a lower substrate having a plurality of electrode pads formed on the outer portion of the top surface thereof; an upper substrate installed on the top surface of the lower substrate, the upper substrate having a window formed in the central portion thereof and a plurality of electrode pads formed on the bottom surface thereof to correspond to the respective electrode pads of the lower substrate, the window exposing the central portion of the top surface of the lower substrate; a conductive member interposed between the electrode pads of the lower substrate and the electrode pads of the upper substrate so as to form a conductive line for electrically connecting the electrode pads; and an image sensor module mounted on the top surface of the upper substrate.

Preferably, each of the electrode pads of the lower substrate is formed to extend to a side surface of the lower substrate.

Preferably, the lower substrate has a plurality of terminal grooves formed in side surfaces thereof, the terminal grooves corresponding to the extended portions of the respective electrode pads.

Preferably, the conductive member is an ACF (Anisotropic Conductive Film) or conductive material.

According to another aspect of the invention, a method of manufacturing an image sensor module comprises mounting various elements on the central portion of the top surface of a lower surface; attaching a conductive member to a plurality of electrode pads formed in the outer portion of the top surface of the lower substrate; installing an upper substrate on the top surface of the lower substrate; and mounting an image sensor on the central portion of the upper substrate.

The method may further comprise filling resin into a window formed in the central portion of the top surface of the upper substrate. The filing of the resin is performed after the installing of the upper substrate.

According to a further aspect of the invention, a camera module comprises an image sensor module; a housing installed on the image sensor module and having an IR cut-off member mounted therein; and a lens barrel installed on the housing and having a lens group mounted therein. The image sensor module includes a lower substrate having a plurality of electrode pads formed on the outer portion of the top surface thereof; an upper substrate installed on the top surface of the lower substrate, the upper substrate having a window formed in the central portion thereof and a plurality of electrode pads formed on the bottom surface thereof to correspond to the respective electrode pads of the lower substrate, the window exposing the central portion of the top surface of the lower substrate; a conductive member interposed between the electrode pads of the lower substrate and the electrode pads of the upper substrate so as to form a conductive line for electrically connecting the electrode pads; and an image sensor module mounted on the top surface of the upper substrate.

According to a still further aspect of the invention, a camera module comprises an image sensor module; an image sensor module mounted on the top surface of the upper substrate; and a barrel-integrated housing mounted on the image sensor module, the barrel-integrated housing having a lens group mounted in an inner upper side thereof and an IR cut-off member mounted in an inner lower side thereof. The image sensor module includes a lower substrate having a plurality of electrode pads formed on the outer portion of the top surface thereof; an upper substrate installed on the top surface of the lower substrate, the upper substrate having a window formed in the central portion thereof and a plurality of electrode pads formed on the bottom surface thereof to correspond to the respective electrode pads of the lower substrate, the window exposing the central portion of the top surface of the lower substrate; a conductive member interposed between the electrode pads of the lower substrate and the electrode pads of the upper substrate so as to form a conductive line for electrically connecting the electrode pads; and an image sensor module mounted on the top surface of the upper substrate.

According to a still further aspect of the invention, a camera module comprises an image sensor module; a housing installed on the image sensor module and having an IR cut-off member mounted therein; an actuator installed on the housing and having a driving device built therein; and a lens barrel having the actuator built therein and a lens group mounted therein, the lens barrel being driven by the driving device. The image sensor module includes a lower substrate having a plurality of electrode pads formed on the outer portion of the top surface thereof; an upper substrate installed on the top surface of the lower substrate, the upper substrate having a window formed in the central portion thereof and a plurality of electrode pads formed on the bottom surface thereof to correspond to the respective electrode pads of the lower substrate, the window exposing the central portion of the top surface of the lower substrate; a conductive member interposed between the electrode pads of the lower substrate and the electrode pads of the upper substrate so as to form a conductive line for electrically connecting the electrode pads; and an image sensor module mounted on the top surface of the upper substrate.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is an exploded perspective view of a conventional COB camera module;

FIG. 2 is an exploded perspective view of a conventional COF camera module;

FIG. 3 is an exploded perspective view of a conventional socket-type camera module;

FIG. 4 is an exploded perspective view of an image sensor module according to a first embodiment of the invention;

FIG. 5 is a partially sectional view of the image sensor module of FIG. 4;

FIG. 6 is a diagram for explaining a method of manufacturing the image sensor module of FIG. 4;

FIG. 7 is an exploded perspective view of an image sensor module according to a second embodiment of the invention;

FIG. 8 is a partially sectional view of the image sensor module of FIG. 7;

FIG. 9 is an exploded perspective view of a camera module to which the image sensor module according to the first embodiment of the invention is applied;

FIG. 10 is a diagram for explaining a method of manufacturing the camera module of FIG. 9;

FIG. 11 is an exploded perspective view of a camera module to which the image sensor module according to the second embodiment of the invention is applied; and

FIG. 12 is an exploded perspective view of a camera module to which an image sensor module according to the third embodiment of the invention is applied.

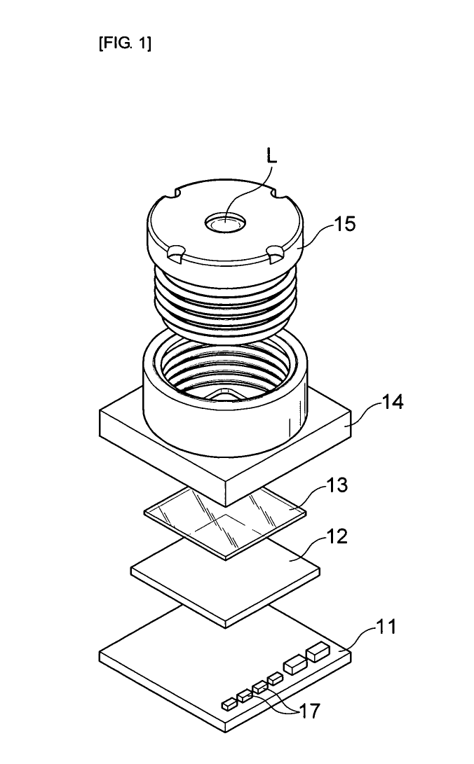

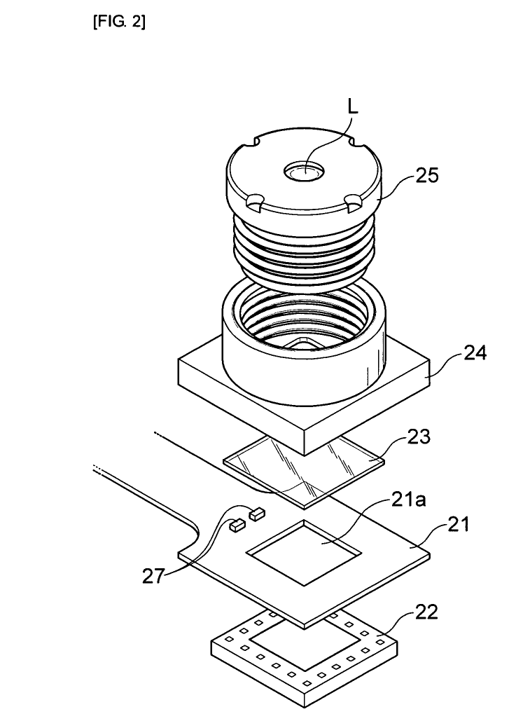

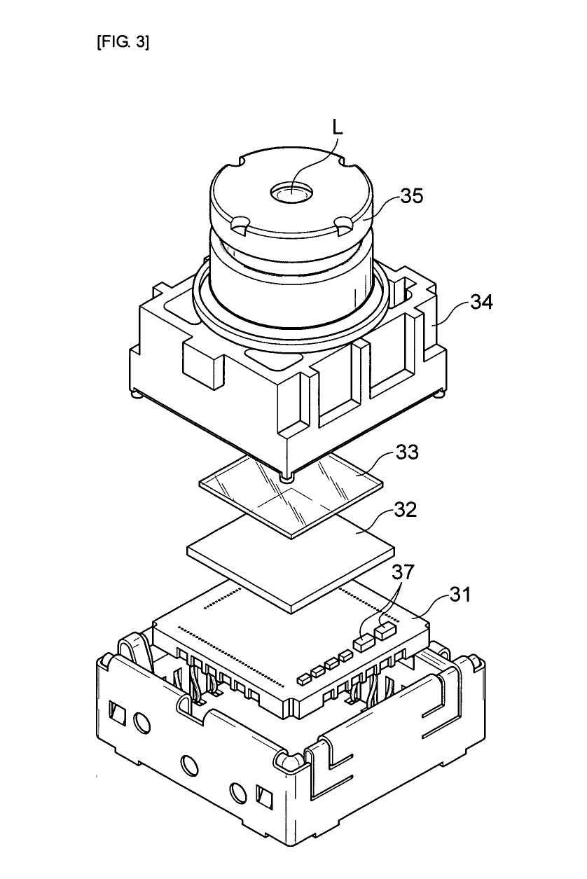

### DETAILED DESCRIPTION OF THE PREFERRED EMBODIMENTS

Reference will now be made in detail to the embodiments of the present general inventive concept, examples of which are illustrated in the accompanying drawings, wherein like reference numerals refer to like elements throughout. The embodiments are described below in order to explain the present general inventive concept by referring to the figures.

Hereinafter, embodiments of the present invention will be described in detail with reference to the accompanying drawings.

### First Embodiment of Image Sensor Module

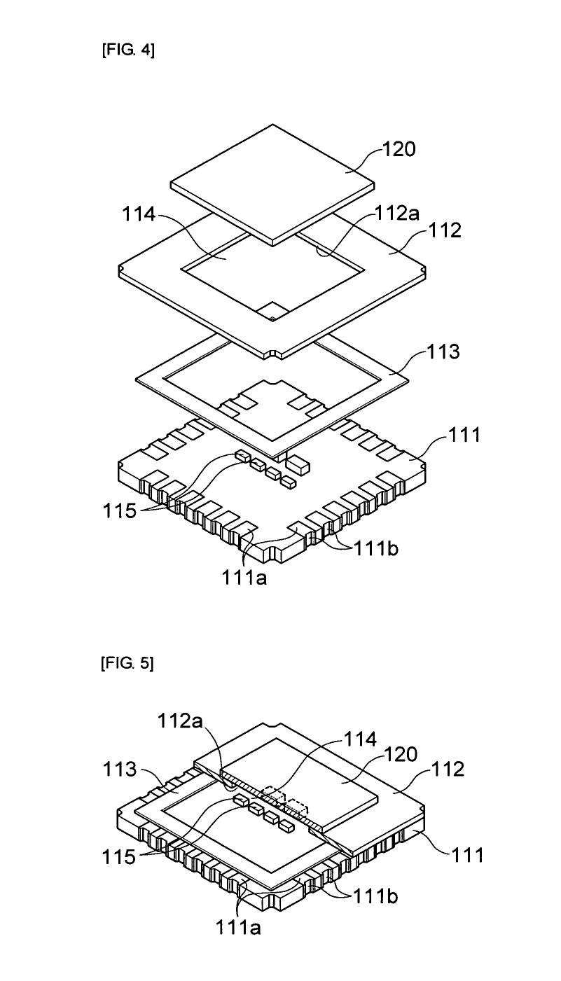

Referring to FIGS. 4 to 6, an image sensor module according to a first embodiment of the invention will be described.

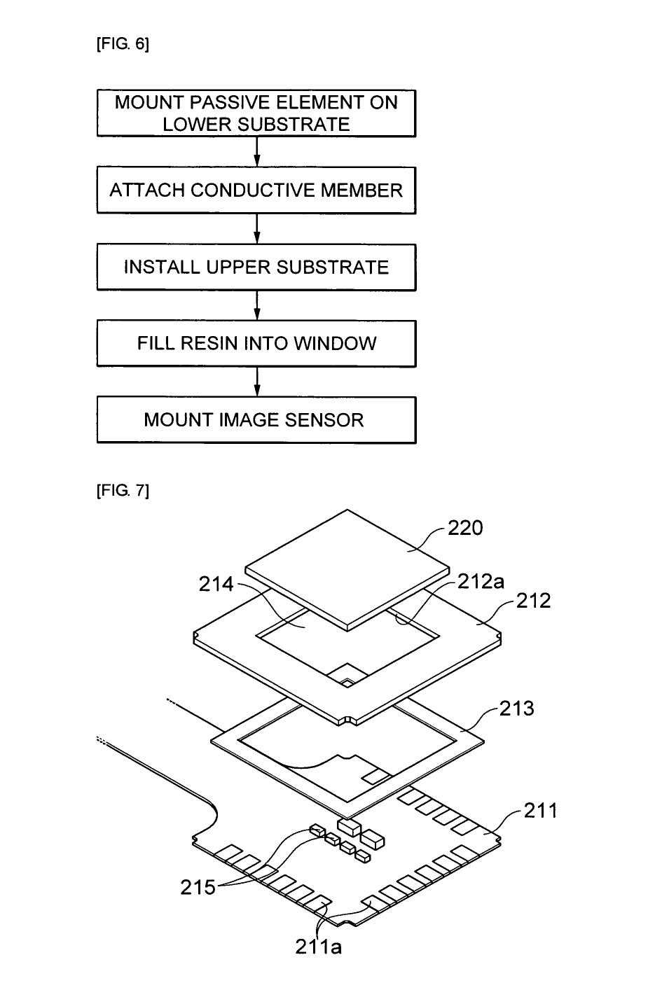

FIG. 4 is an exploded perspective view of an image sensor module according to a first embodiment of the invention. FIG. 5 is a partially sectional view of the image sensor module of FIG. 4. FIG. 6 is a diagram for explaining a method of manufacturing the image sensor module of FIG. 4.

As shown in FIGS. 4 and 5, the image sensor module according to the first embodiment of the invention includes a lower substrate 111 having a plurality of electrode pads 111a formed on the outer portion of the top surface thereof; an upper substrate 112 installed on the top surface of the lower substrate 111, the upper substrate 112 having a window 112a formed in the central portion thereof and a plurality of electrodes pads (not shown) formed on the bottom surface thereof to correspond to the respective electrode pads 111a of the lower substrate 111; a conductive member 113 interposed between the electrode pads 111a of the lower substrate 111 and the electrode pads of the upper substrate 112 so as to form a conductive line for electrically connecting the electrode pads; and an image sensor 120 mounted on the top surface of the upper substrate 112. The window 112a exposes the central portion of the top surface of the lower substrate 111 and provides an air cavity 114 in which various elements 115 are mounted.

Each of the electrode pads 111a of the lower substrate 111 extends to a side surface of the lower substrate 111, where a terminal groove 111b corresponding to the extended portion of the electrode pad 111a is formed.

Through the terminal groove 111b, the image sensor module can be connected to external devices in a socket type.

Preferably, the window 112a of the upper substrate 112 is formed to be smaller than the image sensor 120.

The window 112a of the upper substrate 112 may be formed to be larger than the image sensor 120. In this case, after elements are mounted into the air cavity 114 formed through the window 112a, the air cavity 114 is filled with resin, and then the image sensor 120 can be mounted.

Further, the window 112a may be formed in such a manner that the air cavity 114 is positioned in the outer portion of the lower substrate 111, not in the central portion of the lower substrate 111.

That is, the air cavity 114 may not be positioned right under the image sensor 120.

Meanwhile, the conductive member 113 is composed of an ACF (Anisotropic Conductive Film) formed in a shape corresponding to the disposition of the electrode pads 111a of the lower substrate 111.

That is, the conductive member 113 is composed of a belt-shaped ACF having a central hole corresponding to the window 112a of the upper substrate 112.

As for the conductive member 113, a hot bar, non-conductive polymer, conductive material or the like may be applied instead of the ACF.

The upper and lower substrates 112 and 111 may be formed of an RPCB (Rigid Printed Circuit Board).

Therefore, although the RPCB is used instead of a ceramic substrate of the conventional socket-type camera module, the electrode pads for connection with external devices can be formed on the side surfaces of the substrate. Therefore, while a substrate manufacturing cost is reduced, the RPCB can be applied to the conventional socket-type camera module.

Meanwhile, the upper substrate 112 may be formed of an RPCB, and the lower substrate 111 may be formed of a ceramic circuit.

In the above-described image sensor module according to the first embodiment, a passive element 115 is not mounted on the substrate having the image sensor 120 mounted thereon, but is mounted into the air cavity 114 formed in the center of the lower substrate 111 through the window 112a of the upper substrate 112. Therefore, a space required for installing the passive element 115 on the top surface of the upper substrate 112 having the image sensor 120 mounted thereon can be excluded. Accordingly, the size of the entire substrate composed of the upper and lower substrates 112 and 111 can be reduced into a size corresponding to the size of the image sensor 120, which makes it possible to implement an ultra-small-sized camera module.

Now, a method of manufacturing the image sensor module according to the first embodiment of the invention will be described.

As shown in FIG. 6, the method of manufacturing the image sensor module according to the first embodiment of the invention includes the steps of: mounting the passive element 115 on the lower substrate 111; attaching the conductive member 113; installing the upper substrate 112; filling the window 112a with resin; and mounting the images sensor 120.

More specifically, the passive element 115 for preventing noise of the camera module is mounted on the central portion of the top surface of the lower substrate 111.

Next, the conductive member 113 is attached to the electrode pads 111a formed on the outer portion of the top surface of the lower substrate 111.

Next, the upper substrate 112 is installed on the top surface of the lower substrate 111 such that the electrode pads formed on the bottom surface of the upper surface 112 overlap the electrode pads 111a formed on the top surface of the lower substrate 111.

Then, a conductive line for electrical connection between the upper substrate 112 and the lower substrate 111 through the conductive member 113 is formed.

Next, the inside of the window 112a of the upper substrate 112, that is, the air cavity 114 is filled with resin.

At this time, as for the resin, epoxy-based resin is used. As the inside of the window 112a of the upper substrate 112 is filled with the resin, the subsequent processes can be performed in the same manner as the existing processes without any modification, in a state where the upper and lower substrate 112 and 111 are set to a single substrate.

Next, as the image sensor 120 is mounted on the center of the top surface of the upper substrate 112, the manufacturing of the image sensor module is completed.

### Second Embodiment of Image Sensor Module

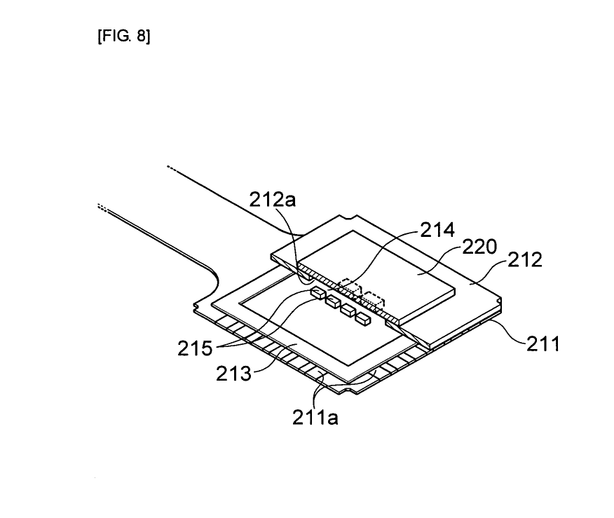

Referring to FIGS. 7 and 8, an image sensor module according to a second embodiment of the invention will be described.

FIG. 7 is an exploded perspective view of an image sensor module according to the second embodiment of the invention. FIG. 8 is a partially sectional view of the image sensor module of FIG. 7.

As shown in FIGS. 7 and 8, the image sensor module according to the second embodiment of the invention includes a lower substrate 211 having a plurality of electrode pads 211a formed on the outer portion of the top surface thereof; an upper substrate 212 installed on the top surface of the lower substrate 211, the upper substrate 212 having a window 212a formed in the central portion thereof and a plurality of electrode pads (not shown) formed on the bottom surface thereof to correspond to the respective electrode pads 211a of the lower substrate 211; a conductive member 213 interposed between the electrode pads 211a of the lower substrate 211 and the electrode pads of the upper substrate 212 so as to form a conductive line for electrically connecting the electrode pads; and an image sensor 220 mounted on the top surface of the upper substrate 212. The window 212a exposes the central portion of the top surface of the lower substrate 211 and provides an air cavity 214 in which various elements 215 are mounted.

In the image sensor module according to the second embodiment of the invention, the upper substrate 212 is composed of an RPCB, and the lower substrate 211 is composed of an FPCB (Flexible Printed Circuit Board), unlike the image sensor module according to the first embodiment of the invention.

In the image sensor module according to the second embodiment of the invention, a passive element 215 is not mounted on the substrate having the image sensor 220 mounted thereon, but is mounted into the air cavity 214, formed in the center of the lower substrate 211, through the window 212a of the upper substrate 212. Therefore, a space required for installing the passive element 215 on the top surface of the upper substrate 212 having the image sensor 220 mounted thereon can be excluded. Accordingly, the size of the entire substrate composed of the upper and lower substrates 212 and 211 can be reduced into a size corresponding to the size of the image sensor 220, which makes it possible to implement an ultra-small-sized camera module.

Further, after the upper substrate 212 on which the image sensor 220 is mounted is manufactured, the FPCB serving as the lower substrate 211 for connection with an external device can be separately manufactured. Therefore, it is possible to commonly manufacture modules and to modify an interface and FPCB in accordance with a user's request.

Meanwhile, a method of manufacturing the image sensor module according to the second embodiment of the invention is similar to the method of manufacturing the image sensor module according to the first embodiment of the invention, and thus the descriptions thereof will be omitted.

Camera Module to which Image Sensor Module According to First Embodiment is Applied

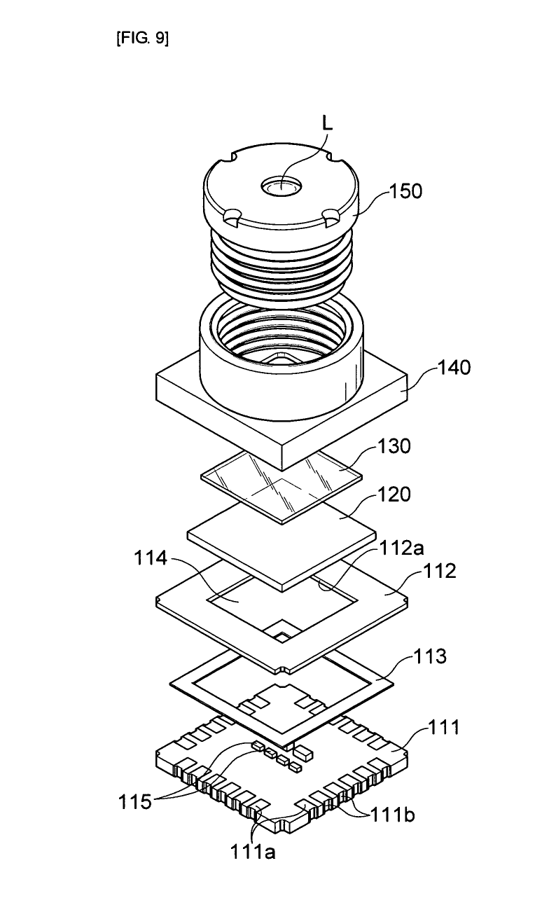

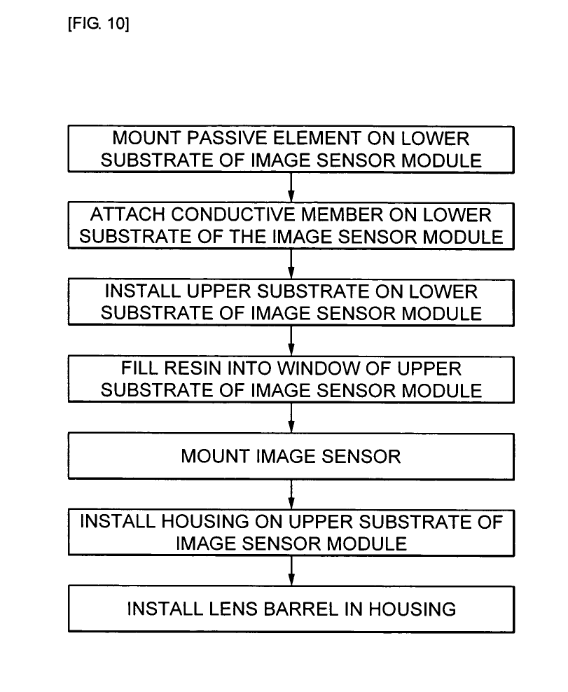

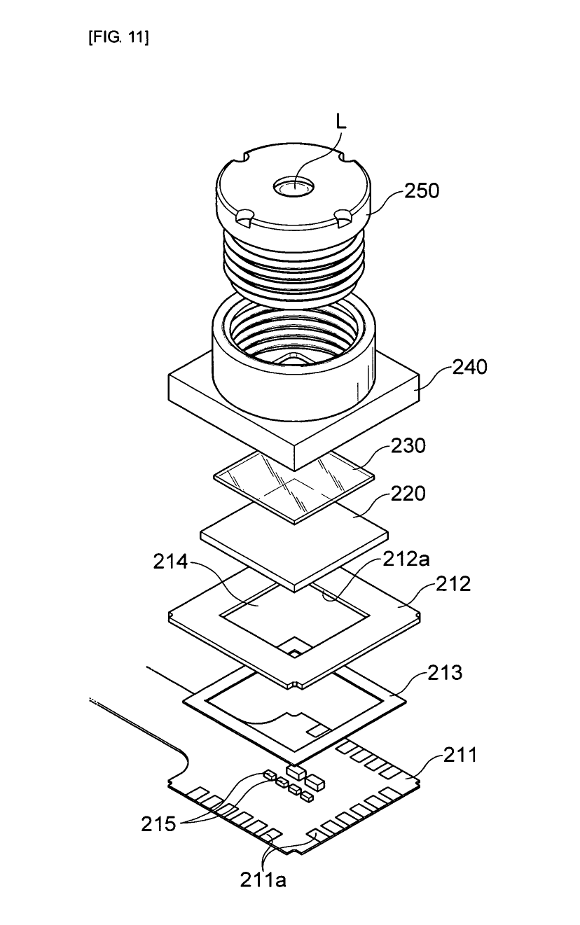

Referring to FIGS. 9 and 10, a camera module to which the image sensor module according to the first embodiment is applied will be described.

FIG. 9 is an exploded perspective view of a camera module to which the image sensor module according to the first embodiment of the invention is applied. FIG. 10 is a diagram for explaining a method of manufacturing the camera module of FIG. 9.

As shown in FIG. 9, the camera module to which the image sensor module according to the first embodiment of the invention is applied includes the image sensor module, a housing 140 installed on the image sensor module and having an IR cut-off member 130 mounted therein, and a lens barrel 150 installed on the housing 140 and having a lens group L mounted therein.

As described above, the image sensor module according to the first embodiment includes a lower substrate 111 having a plurality of electrode pads 111a formed on the outer portion of the top surface thereof; an upper substrate 112 installed on the top surface of the lower substrate 111, the upper substrate 112 having a window 112a formed in the central portion of the top surface thereof and a plurality of electrodes pad (not shown) formed on the bottom surface thereof to correspond to the respective electrode pads 111a of the lower substrate 111; a conductive member 113 interposed between the electrode pads 111a of the lower substrate 111 and the electrode pads of the upper substrate 112 so as to form a conductive line for electrically connecting the electrode pads; and an image sensor 120 mounted on the top surface of the upper substrate 112. The window 112a exposes the central portion of the top surface of the lower substrate 111 and provides an air cavity 114 in which various elements 115 are mounted.

Each of the electrode pads 111a of the lower substrate 111 extends to a side surface of the lower substrate 111, where a terminal groove 111b corresponding to the extended portion of the electrode pad 111a is formed.

Further, the window 112a of the upper substrate 112 is formed to be smaller than the image sensor 120.

The window 112a of the upper substrate 112 may be formed to be larger than the image sensor 120. In this case, after elements are mounted into the air cavity 114 formed through the window 112a, the air cavity 114 is filled with resin, and then the image sensor 120 can be mounted.

Further, the window 112a may be formed in such a manner that the air cavity 114 is positioned in the outer portion of the lower substrate 111, not in the central portion of the lower substrate 111.

That is, the air cavity 114 may not be positioned right under the image sensor 120.

The conductive member 113 is an ACF formed in a shape corresponding to the disposition of the electrode pads 111a of the lower substrate 111.

As for the conductive member 113, a hot bar, non-conductive polymer, conductive material or the like may be applied instead of the ACF.

The upper and lower substrates 112 and 111 may be formed of an RPCB.

Alternately, the upper substrate 112 may be formed of an RPCB, and the lower substrate 111 may be formed of a ceramic circuit.

Therefore, in the camera module to which the image sensor module according to the first embodiment is applied, a passive element 115 is not mounted on the substrate having the image sensor 120 mounted thereon, but is mounted into the air cavity 114 formed in the center of the lower substrate 111 through the window 112a of the upper substrate 112. Therefore, a space required for installing the passive element 115 on the top surface of the upper substrate 112 having the image sensor 120 mounted thereon can be excluded. Accordingly, the size of the entire substrate composed of the upper and lower substrates 112 and 111 can be reduced into a size corresponding to the size of the image sensor 120, which makes it possible to implement an ultra-small-sized camera module.

Further, after the upper substrate 212 on which the image sensor 220 is mounted is manufactured, the lower substrate 211 for connection with an external device can be separately manufactured. Therefore, it is possible to commonly manufacture modules and to modify an interface and FPCB in accordance with a user's request.

In the above-described camera module, while the lens barrel 150 is coupled to the upper portion of the housing 140 through a screw, a distance between the lens group L and a light receiving section of the image sensor 120 is adjusted so as to adjust the focus of the camera module. Instead of the housing 140 and the lens barrel 150, however, a barrel-integrated housing may be used, in which the lens group is mounted in the inner upper side thereof and the IR cut-off member is mounted in the inner lower side thereof.

That is, the barrel-integrated housing is referred to as a housing in which a focal distance between the lens group mounted therein and the image sensor 120 mounted on the upper substrate 112 coupled to the lower portion of the housing is adjusted in advance.

In a camera module in which the barrel-integrated housing is used, the image sensor module according to the first embodiment is applied.

Now, a method of manufacturing the camera module to which the image sensor module according to the first embodiment of the invention is applied will be described.

As shown in FIG. 10, the method includes the steps of: mounting the passive element 115 on the lower substrate 111, attaching the conductive member 113, installing the upper substrate 112, filling the window 112a with resin, mounting the image sensor 120, installing the housing 140, and installing the lens barrel 150.

That is, the method of manufacturing the camera module to which the image sensor module according to the first embodiment of the invention is applied further includes the steps of: installing the housing 140, and installing the lens barrel 150, in addition to the method of manufacturing the image sensor module according to the first embodiment.

Therefore, the descriptions of the method of manufacturing the image sensor module are omitted, and the subsequent processes will be described.

When the image sensor module is completely manufactured, the IR cut-off member 130 is mounted on a step portion formed in the inner lower side of the housing 140, and the lens group L is mounted into the lens barrel 150.

The mounting of the IR cut-off member 130 and the mounting of the lens group L may be performed before or simultaneously when the image sensor module is manufactured.

After that, the housing 140 is installed on the image sensor module.

That is, the housing 140 is installed on the upper substrate 112 of the image sensor module through an adhesive.

Further, when the lens barrel 150 is coupled to the upper portion of the housing 140 through a screw, the focus of the camera module is adjusted while a distance between the lens group L and the light receiving section of the image sensor 120 is adjusted.

When the focus adjustment is completed, an adhesive is injected between the housing 140 and the lens barrel 150. As the adhesive is solidified, the housing 140 and the lens barrel 156 are fixed to each other such that the camera module is completely manufactured.

Camera Module to which Image Sensor Module According to Second Embodiment is Applied

Referring to FIG. 11, a camera module to which the image sensor module according to the second embodiment of the invention will be described.

FIG. 11 is an exploded perspective view of a camera module to which the image sensor module according to the second embodiment of the invention is applied.

As shown in FIG. 11, the camera module includes the image sensor module according to the second embodiment, a housing 240 installed on the image sensor module and having an IR cut-off member 230 mounted therein, and a lens barrel 250 installed on the housing 240 and having a lens group L mounted therein.

As described above, the image sensor module according to the second embodiment of the invention includes a lower substrate 211 having a plurality of electrode pads 211a formed on the outer portion of the top surface thereof; an upper substrate 212 installed on the top surface of the lower substrate 211, the upper substrate 212 having a window 212a formed in the central portion thereof and a plurality of electrode pads (not shown) formed on the bottom surface thereof to correspond to the respective electrode pads 211a of the lower substrate 211; a conductive member 213 interposed between the electrode pads 211a of the lower substrate 211 and the electrode pads of the upper substrate 212 so as to form a conductive line for electrically connecting the electrode pads; and an image sensor 220 mounted on the top surface of the upper substrate 212. The window 212a exposes the central portion of the top surface of the lower substrate 211 and provides an air cavity 214 in which various elements 215 are mounted.

In the image sensor module according to the second embodiment of the invention, the upper substrate 212 is composed of an RPCB, and the lower substrate 211 is composed of an FPCB.

In the camera module to which the image sensor module according to the second embodiment of the invention is applied, a passive element 215 is not mounted on the substrate having the image sensor 220 mounted thereon, but is mounted into the air cavity 214 formed in the center of the lower substrate 211 through the window 212a of the upper substrate 212. Therefore, a space required for installing the passive element 215 on the top surface of the upper substrate 212 having the image sensor 220 mounted thereon can be excluded. Accordingly, the size of the entire substrate composed of the upper and lower substrates 212 and 211 can be reduced into a size corresponding to the size of the image sensor 220, which makes it possible to implement an ultra-small-sized camera module.

Further, after the upper substrate 212 on which the image sensor 220 is mounted is manufactured, the FPCB serving as the lower substrate 211 for connection with an external device can be separately manufactured. Therefore, it is possible to commonly manufacture modules and to modify an interface and FPCB in accordance with a user's request.

As in the camera module to which the image sensor module according to the first embodiment is applied, while the lens barrel 250 is coupled to the upper portion of the housing 240 through a screw, a distance between the lens group L and the light receiving section of the image sensor 220 is adjusted so as to adjust the focus of the camera module. Instead of the housing 240 and the lens barrel 250, however, a barrel-integrated housing may be used, in which the lens group is mounted in the inner upper side thereof and the IR cut-off member is mounted in the inner lower side thereof.

That is, the barrel-integrated housing is referred to as a housing in which a focal distance between a lens group mounted in the housing and an image sensor mounted on a substrate coupled to the lower portion of the housing is adjusted in advance.

In a camera module in which the barrel-integrated housing is used, the image sensor module according to the second embodiment is applied.

Meanwhile, a method of manufacturing the camera module to which the image sensor module according to the second embodiment is applied is similar to the method of manufacturing the camera module to which the image sensor module according to the first embodiment is applied, and thus the descriptions thereof will be omitted.

### Third Embodiment of Image Sensor Module and Camera Module having the Same

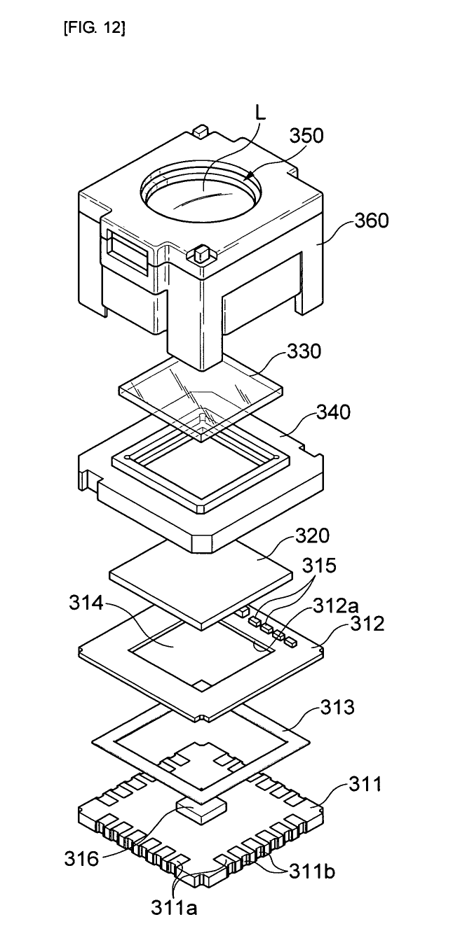

Referring to FIG. 12, an image sensor module according to a third embodiment of the invention and a camera module having the image sensor will be described in detail.

FIG. 12 is an exploded perspective view of a camera module to which an image sensor module according to the third embodiment of the invention is applied.

As shown in FIG. 12, the image sensor module according to the third embodiment may be applied to a camera module having an auto-focusing function.

More specifically, the image sensor module according to the third embodiment of the invention is provided in a camera module with an actuator 360. The image sensor module includes a lower substrate 311 having a plurality of electrode pads 311a formed on the outer portion of the top surface thereof; an upper substrate 312 installed on the top surface of the lower substrate 311, the upper substrate 312 having a window 312a formed in the central portion thereof and a plurality of electrode pads (not shown) formed on the bottom surface thereof to correspond to the respective electrode pads 311a of the lower substrate 311; a conductive member 213 interposed between the electrode pads 311a of the lower substrate 211 and the electrode pads of the upper substrate 312 so as to form a conductive line for electrically connecting the electrode pads; and an image sensor 320 mounted on the top surface of the upper substrate 312. The window 312a exposes the central portion of the top surface of the lower substrate 311 and provides an air cavity 314 in which a drive IC (integrated circuit) 316 is mounted, the drive IC 316 controlling the operation of a driving device (not shown) built in the actuator 360.

That is, in the image sensor module according to the third embodiment of the invention, the drive IC 316 is mounted in the air cavity 314 formed in the center of the lower substrate 311 through the coupling to the upper substrate 312.

The drive IC circuit 316 serves to control the operation of the driving device built in the actuator 360 so as to control the vertical movement of the lens barrel 350. Typically, the drive IC circuit 316 is much larger than a passive element 315 for preventing noise of a camera module.

Therefore, the image sensor module according to the third embodiment of the invention has such a structure that the drive IC 316 is mounted in the air cavity 314 formed in the center of the lower substrate 311 and the passive element 315 is mounted in one side of the image sensor 320 mounted on the top surface of the upper substrate 312.

The passive element 315 mounted on the upper substrate 312 as well as the drive IC 316 may be formed in the air cavity 34 formed in the lower substrate 311.

Further, the camera module having the image sensor module according to the third embodiment of the invention includes the lens barrel 350 having a lens group L mounted therein, the actuator 360 having a driving device (not shown) for vertically driving the lens barrel 350, a housing 340 installed under the actuator 360, and the image sensor module according to the third embodiment which is installed under the housing 340.

The housing 340 has a step portion formed therein, and an IR cut-off member 360 is mounted on the step portion so as to cut off infrared light included in light incident on the light receiving section of the image sensor 320 through the lens group L.

The upper and lower substrates 312 and 311 of the image sensor module may be all formed of an RPCB.

Alternately, the upper substrate 312 may be formed of an RPCB, and the lower substrate 311 may be formed of a ceramic circuit.

Alternately, the upper substrate 312 may be formed of an RPCB, and the lower substrate 311 may be formed of an FPCB.

In the image sensor module according to the third embodiment of the invention and the camera module having the image sensor module, the drive IC circuit 316 for operating the driving device of the actuator 360 is not mounted on the substrate having the image sensor 320 mounted thereon, but is mounted into the air cavity 314 formed in the center of the lower substrate 311 through the window 312a of the upper substrate 312. Therefore, a space required for installing the drive IC circuit 316 on the substrate having the image sensor 320 mounted thereon can be excluded. Accordingly, the size of the entire substrate composed of the upper and lower substrates 312 and 311 can be reduced into a size corresponding to the size of the image sensor 320, which makes it possible to implement an ultra-small-sized camera module.

Meanwhile, the actuator 360 can be applied to various driving functions such as an auto-focusing function, an optical zoom function and the like, in addition to the function for vertically driving the lens barrel.

In a method of manufacturing the image sensor module according to the third embodiment of the invention and the camera module having the image sensor module, the respective components from the lower substrate 311 to the actuator 360 can be sequentially manufactured in a stacked order by referring to FIG. 12. Therefore, the detailed descriptions thereof are omitted.

According to the image sensor module, the method of manufacturing the same, and the camera module having the same, the reduction in size can be achieved, and the manufacturing time can be reduced. Therefore, it is possible to reduce a manufacturing cost.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

What is claimed is:

1. An image sensor module comprising:
a lower substrate having a plurality of electrode pads formed on the outer portion of the top surface thereof;
an upper substrate installed on the top surface of the lower substrate, the upper substrate having a window formed in the central portion thereof and a plurality of electrode pads formed on the bottom surface thereof to correspond to the respective electrode pads of the lower substrate, the window exposing the central portion of the top surface of the lower substrate;
a conductive member interposed between the electrode pads of the lower substrate and the electrode pads of the upper substrate so as to form a conductive line for electrically connecting the electrode pads; and
an image sensor module mounted on the top surface of the upper substrate.

2. The image sensor module according to claim 1, wherein each of the electrode pads of the lower substrate is formed to extend to a side surface of the lower substrate.

3. The image sensor module according to claim 2, the lower substrate has a plurality of terminal grooves formed in side surfaces thereof, the terminal grooves corresponding to the extended portions of the respective electrode pads.

4. The image sensor module according to claim 1, wherein the conductive member is an ACF (Anisotropic Conductive Film) or conductive material.

5. A method of manufacturing an image sensor module, the method comprising:
mounting various elements on the central portion of the top surface of a lower surface;
attaching a conductive member to a plurality of electrode pads formed in the outer portion of the top surface of the lower substrate;
installing an upper substrate on the top surface of the lower substrate; and
mounting an image sensor on the central portion of the upper substrate.

6. The method according to claim 5 further comprising:
filling resin into a window formed in the central portion of the top surface of the upper substrate,
wherein the filing of the resin is performed after the installing of the upper substrate.

7. A camera module comprising:
an image sensor module including:
a lower substrate having a plurality of electrode pads formed on the outer portion of the top surface thereof;
an upper substrate installed on the top surface of the lower substrate, the upper substrate having a window formed in the central portion thereof and a plurality of electrode pads formed on the bottom surface thereof to correspond to the respective electrode pads of the lower substrate, the window exposing the central portion of the top surface of the lower substrate;
a conductive member interposed between the electrode pads of the lower substrate and the electrode pads of the upper substrate so as to form a conductive line for electrically connecting the electrode pads; and
an image sensor module mounted on the top surface of the upper substrate;
a housing installed on the image sensor module and having an IR cut-off member mounted therein; and
a lens barrel installed on the housing and having a lens group mounted therein.

8. A camera module comprising:
an image sensor module including:
a lower substrate having a plurality of electrode pads formed on the outer portion of the top surface thereof;
an upper substrate installed on the top surface of the lower substrate, the upper substrate having a window formed in the central portion thereof and a plurality of electrode pads formed on the bottom surface thereof to correspond to the respective electrode pads of the lower substrate, the window exposing the central portion of the top surface of the lower substrate;
a conductive member interposed between the electrode pads of the lower substrate and the electrode pads of the upper substrate so as to form a conductive line for electrically connecting the electrode pads; and
an image sensor module mounted on the top surface of the upper substrate; and
a barrel-integrated housing mounted on the image sensor module, the barrel-integrated housing having a lens group mounted in an inner upper side thereof and an IR cut-off member mounted in an inner lower side thereof.

9. A camera module comprising
an image sensor module including:
a lower substrate having a plurality of electrode pads formed on the outer portion of the top surface thereof;
an upper substrate installed on the top surface of the lower substrate, the upper substrate having a window formed in the central portion thereof and a plurality of electrode pads formed on the bottom surface thereof to correspond to the respective electrode pads of the lower substrate, the window exposing the central portion of the top surface of the lower substrate;
a conductive member interposed between the electrode pads of the lower substrate and the electrode pads of the upper substrate so as to form a conductive line for electrically connecting the electrode pads; and
an image sensor module mounted on the top surface of the upper substrate;
a housing installed on the image sensor module and having an IR cut-off member mounted therein;
an actuator installed on the housing and having a driving device built therein; and
a lens barrel having the actuator built therein and a lens group mounted therein, the lens barrel being driven by the driving device.
